(19) United States
(12) Patent Application Publication
(10) Pub. No.: US 2025/0284209 A1
(43) Pub. Date: Sep. 11, 2025

(54) METHOD AND SYSTEM OF OVERLAY MEASUREMENT USING CHARGED-PARTICLE INSPECTION APPARATUS

(71) Applicant: ASML NETHERLANDS B.V., Veldhoven (NL)

(72) Inventors: Antoine Gaston Marie KIERS, Veldhoven (NL); Benoit Herve GAURY, Eindhoven (NL); Thomas Jarik HUISMAN, Eindhoven (NL)

(73) Assignee: ASML NETHERLANDS B.V., Veldhoven (NL)

(21) Appl. No.: 18/861,859

(22) PCT Filed: Jul. 6, 2023
(86) PCT No.: PCT/EP2023/068636

§ 371 Date: Oct. 30, 2024

(30) Foreign Application Priority Data
Jul. 15, 2022 (EP) 22185195.9

(51) Int. Cl. G03F 7/00

(52) U.S. Cl. CPC G03F 7/706839; G03F 7/70655

(57) ABSTRACT

A system, including: a charged-particle beam inspection apparatus configured to scan a sample that includes a target with a plurality of pattern layers; and a controller including circuitry, configured to: obtain detection data in response to a scan of the target; and determine one or more characteristics of the sample in dependence on the obtained detection data and a model, wherein, for each of the plurality of pattern layers of the target, the model has a term that is dependent on the properties of the pattern layer.

### FIELD

The description herein relates to the field of image inspection apparatus, and more particularly to the measurement of characteristics of a sample by a charged-particle inspection apparatus. The measured characteristics of the sample may include overlay.

### BACKGROUND

An image inspection apparatus (e.g., a charged-particle beam apparatus or an optical beam apparatus) is able to produce a two-dimensional (2D) image of a wafer substrate by detecting particles (e.g., photons, secondary electrons, backscattered electrons, mirror electrons, or other kinds of electrons) from a surface of a wafer substrate upon impingement by a beam (e.g., a charged-particle beam or an optical beam) generated by a source associated with the inspection apparatus. Various image inspection apparatuses are used on semiconductor wafers in semiconductor industry for various purposes such as wafer processing (e.g., e-beam direct write lithography system), process monitoring (e.g., critical dimension scanning electron microscope (CD-SEM)), wafer inspection (e.g., e-beam inspection system), or defect analysis (e.g., defect review SEM, or say DR-SEM and Focused Ion Beam system, or say FIB).

In semiconductor manufacturing, integrated circuits may be fabricated as one or more stacked layers of materials (e.g., silicon, silicon dioxide, metal, or the like) on a wafer. Each layer of material may include a designed pattern (referred to as a “pattern layer” herein) for forming components (e.g., transistors, contacts, or the like) of the integrated circuits. The fabrication of each layer involves transferring a pattern from a mask onto the wafer surface through a lithography process. The position of each pattern layer relative to its previous pattern layer (referred to as “alignment” herein) may influence characteristics or quality of the manufactured integrated circuits.

Overlay refers to a planar, vectorial shift, displacement, or misalignment of a pattern layer with respect to its neighboring pattern layer. For example, two intra-pattern reference points (e.g., center points) may be selected for two patterns in two neighboring pattern layers, respectively, and the overlay between the two neighboring pattern layers may refer to a planar, vectorial displacement between the two intra-pattern reference points. Large overlay may cause problems or failures of the manufactured integrated circuits. Therefore, high-precision overlay measurement plays an important role in reducing the overlay.

### SUMMARY

Embodiments of the present disclosure provide systems and methods of measuring a characteristic of a sample under a scan performed by a charged-particle beam inspection apparatus. In some embodiments, there is provided a system comprising: a charged-particle beam inspection apparatus configured to scan a sample that comprises a target with a plurality of pattern layers; and a controller including circuitry, configured to: obtain detection data in response to a scan of the target; and determine one or more characteristics of the sample in dependence on the obtained detection data and a model; wherein, for each of the plurality of pattern layers of the target, the model comprises a term that is dependent on the properties of the pattern layer. In some embodiments, there is provided a non-transitory computer-readable medium that stores a set of instructions that is executable by at least one processor of an apparatus to cause the apparatus to perform a method, the method comprising: obtaining detection data in response to a scan of a target by a charged particle beam inspection apparatus; determining one or more characteristics of the sample in dependence on the obtained detection data and a model; wherein the target comprises a plurality of pattern layers and, for each of the plurality of pattern layers, the model comprises a term that is dependent on the properties of the pattern layer. In some embodiments, there is provided a computer-implemented method of measuring characteristics of a sample under a scan performed by a charged-particle beam inspection apparatus, the method comprising: obtaining detection data in response to a scan of a target by a charged particle beam inspection apparatus; determining one or more characteristics of the sample in dependence on the obtained detection data and a model; wherein the target comprises a plurality of pattern layers and, for each of the plurality of pattern layers, the model comprises a term that is dependent on the properties of the pattern layer.

### BRIEF DESCRIPTION OF THE DRAWINGS

FIG. 1 is a schematic diagram illustrating an example charged-particle beam inspection (CPBI) system, consistent with some embodiments of the present disclosure.

FIG. 2 is a schematic diagram illustrating an example charged-particle beam tool, consistent with some embodiments of the present disclosure that may be a part of the example charged-particle beam inspection system of FIG. 1.

FIG. 3 is a schematic diagram illustrating an example target manufactured on a sample, consistent with some embodiments of the present disclosure.

FIG. 4A shows a modelled signal and its components according to some embodiments. consistent with some embodiments of the present disclosure.

FIG. 4B shows a residual signal, or error signal, that represents the difference between a measured and a modelled signal according to some embodiments.

FIG. 5 shows a modelled signal according to some embodiments when fitted to measured data.

FIG. 6 is a flowchart illustrating an example method of characteristic measurement, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them may be fit on the substrate. For example, an IC chip in a smartphone may be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection may be carried out using a scanning charged-particle microscope (“SCPM”). For example, a scanning charged-particle microscope may be a scanning electron microscope (SEM). A scanning charged-particle microscope may be used to image these extremely small structures, in effect, taking a “picture” of the structures of the wafer. The image may be used to determine if the structure was formed properly in the proper location. If the structure is defective, then the process may be adjusted, so the defect is less likely to recur.

The working principle of a scanning charged-particle microscope (e.g., a SEM) is similar to a camera. A camera takes a picture by receiving and recording intensity of light reflected or emitted from people or objects. A scanning charged-particle microscope takes a “picture” by receiving and recording energies or quantities of charged particles (e.g., electrons) reflected or emitted from the structures of the wafer. Typically, the structures are made on a substrate (e.g., a silicon substrate) that is placed on a platform, referred to as a stage, for imaging. Before taking such a “picture,” a charged-particle beam may be projected onto the structures, and when the charged particles are reflected or emitted (“exiting”) from the structures (e.g., from the wafer surface, from the structures underneath the wafer surface, or both), a detector of the scanning charged-particle microscope may receive and record the energies or quantities of those charged particles to generate an inspection image. To take such a “picture,” the charged-particle beam may scan over the wafer (e.g., in a line-by-line or zig-zag manner), and the detector may receive exiting charged particles coming from a region under charged particle-beam projection (referred to as a “beam spot”). The detector may receive and record exiting charged particles from each beam spot one at a time and join the information recorded for all the beam spots to generate the inspection image. Some scanning charged-particle microscopes use a single charged-particle beam (referred to as a “single-beam scanning charged-particle microscope,” such as a single-beam SEM) to take a single “picture” to generate the inspection image, while some scanning charged-particle microscopes use multiple charged-particle beams (referred to as a “multi-beam scanning charged-particle microscope,” such as a multi-beam SEM) to take multiple “sub-pictures” of the wafer in parallel and stitch them together to generate the inspection image. By using multiple charged-particle beams, the SEM may provide more charged-particle beams onto the structures for obtaining these multiple “sub-pictures,” resulting in more charged particles exiting from the structures. Accordingly, the detector may receive more exiting charged particles simultaneously and generate inspection images of the structures of the wafer with higher efficiency and faster speed.

To control quality of the manufactured semiconductor structures, various overlay measurement techniques may be used. Typically, overlay may be measured using optical tools. For example, a broadband light beam may be shed on a surface of a sample. The surface may include a specifically designed and manufactured structure (also referred to as “target” herein). The target may include a first layer (e.g., a top layer) and a second layer (e.g., a bottom layer) below the first pattern layer. An optical scatterometry tool may be used to measure reflection or diffraction of the broadband light reflected by the target. The reflection or diffraction may have various characteristics, such as different wavelengths, polarization, angle-of-incidence, phases, or other optical characteristics, from which unknown properties (e.g., overlay) of the sample may be determined.

By way of example, the overlay of a target may be determined based on a phase difference between diffractions of a first layer (e.g., a top layer) and a second layer (e.g., a layer beneath the first layer), each of the first layer and the second layer including a specific structure (e.g., a grating). The overlay determined using such a target may be referred to as a diffraction-based overlay (“DBO”). To measure a diffraction-based overlay, structures (e.g., gratings) in the first player and the second player may be manufactured with a programmed shift. A programmed shift between two layers herein may refer to a designed (known) planar, vectorial displacement between the two layers. The programmed shift may be used to remove or reduce imperfections in the optical scatterometry measurements.

Several technical challenges exist in the optical based overlay measurement techniques. A first challenge is that signals of the reflection or diffraction become weaker as a pitch of the target (e.g., a pitch of a grating) decreases and as separation between neighboring pattern layers increases. A “pitch” in this disclosure refers to the minimum center-to-center distance between interconnect lines in a manufactured integrated circuit, which may be used as an indicator of an integration level of the integrated circuit. A second challenge is that selecting a wavelength of the broadband light beam for the optical based overlay measurement techniques may be complicated because each wavelength may yield different measurement results. A third challenge is that measurement results of the optical based overlay measurement techniques may be sensitive to subtle tilts of areas between lines of the targets (e.g., lines of the gratings). Those challenges may increase the uncertainties and inaccuracy in the overlay measurements.

Embodiments of the present disclosure may provide methods, apparatuses, and systems for non-optical overlay measurement. In some disclosed embodiments, a scanning charged-particle microscope (e.g., a SEM) may be used for overlay measurements using one or more targets. The scanning charged-particle microscope may inject a charged-particle beam (e.g., an electron beam) onto a surface of the one or more targets, each of which includes a first layer (e.g., a top layer) and a second layer (e.g., below the first layer). Each of the first layer and the second layer may include a similar pattern (e.g., a grating). The incident charged-particle beam may interact with the pattern in the first layer and the pattern in the second layer to generate secondary electrons and backscattered electrons. The outgoing secondary electrons and backscattered electrons may be detected by a detector to generate signals. By analysis of the signals, an overlay between the first layer and the second layer may be determined. Compared with the optical based overlay measurement techniques, the non-optical overlay measurement may reduce or remove the above-described challenges, and accuracy of the overlay measurement may be greatly improved.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

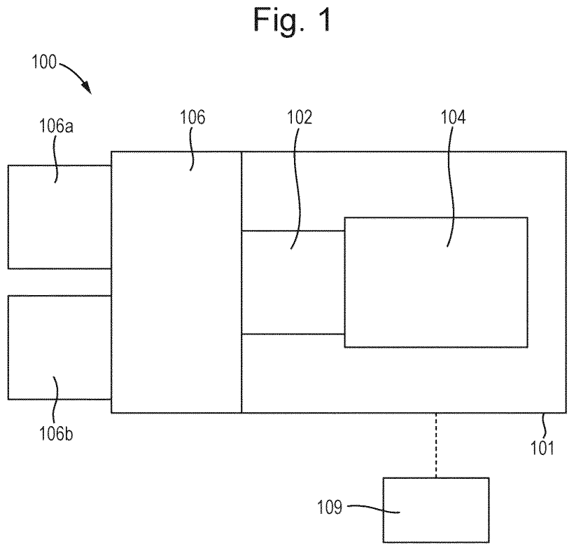

FIG. 1 illustrates an exemplary charged-particle beam inspection (CPBI) system 100 consistent with some embodiments of the present disclosure. CPBI system 100 may be used for imaging. For example, CPBI system 100 may use an electron beam for imaging. As shown in FIG. 1, CPBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer that may execute various controls of CPBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

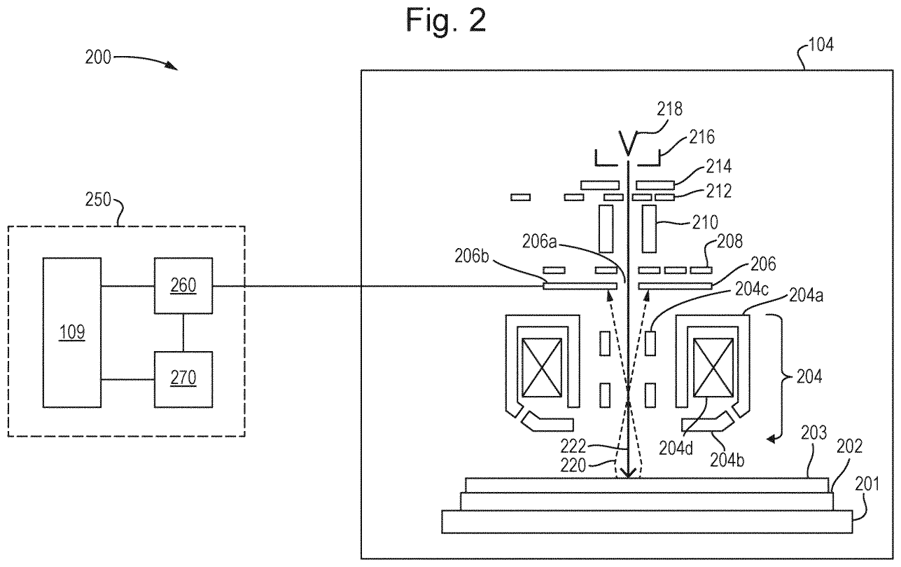

FIG. 2 illustrates an example imaging system 200 according to embodiments of the present disclosure. Beam tool 104 of FIG. 2 may be configured for use in CPBI system 100. Beam tool 104 may be a single beam apparatus or a multi-beam apparatus. As shown in FIG. 2, beam tool 104 includes a motorized sample stage 201, and a wafer holder 202 supported by motorized sample stage 201 to hold a wafer 203 to be inspected. Beam tool 104 further includes an objective lens assembly 204, a charged-particle detector 206 (which includes charged-particle sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Beam tool 104 may additionally include an Energy Dispersive X-ray Spectrometer (EDS) detector (not shown) to characterize the materials on wafer 203.

A primary charged-particle beam 220 (or simply “primary beam 220”), such as an electron beam, is emitted from cathode 218 by applying an acceleration voltage between anode 216 and cathode 218. Primary beam 220 passes through gun aperture 214 and beam limit aperture 212, both of which may determine the size of charged-particle beam entering condenser lens 210, which resides below beam limit aperture 212. Condenser lens 210 focuses primary beam 220 before the beam enters objective aperture 208 to set the size of the charged-particle beam before entering objective lens assembly 204. Deflector 204c deflects primary beam 220 to facilitate beam scanning on the wafer. For example, in a scanning process, deflector 204c may be controlled to deflect primary beam 220 sequentially onto different locations of top surface of wafer 203 at different time points, to provide data for image reconstruction for different parts of wafer 203. Moreover, deflector 204c may also be controlled to deflect primary beam 220 onto different sides of wafer 203 at a particular location, at different time points, to provide data for stereo image reconstruction of the wafer structure at that location. Further, in some embodiments, anode 216 and cathode 218 may generate multiple primary beams 220, and beam tool 104 may include a plurality of deflectors 204c to project the multiple primary beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary beam 220 may be immersed in the magnetic field and may be electrically charged, which, in turn, creates an electric field. The electric field reduces the energy of impinging primary beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary charged-particle beam 222 (or “secondary beam 222”), such as secondary electron beams, may be emitted from the part of wafer 203 upon receiving primary beam 220. Secondary beam 222 may form a beam spot on sensor surfaces 206a and 206b of charged-particle detector 206. Charged-particle detector 206 may generate a signal (e.g., a voltage, a current, or the like.) that represents an intensity of the beam spot and provide the signal to an image processing system 250. The intensity of secondary beam 222, and the resultant beam spot, may vary according to the external or internal structure of wafer 203. Moreover, as discussed above, primary beam 220 may be projected onto different locations of the top surface of the wafer or different sides of the wafer at a particular location, to generate secondary beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or the like. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, post-processed images, or other images assisting of the processing. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

In an measurement process of a surface structure and a sub-surface structure using a charged-particle beam tool (e.g., a scanning charged-particle microscope), a scanning charged-particle microscope (“SCPM”) generates a primary charged-particle beam (e.g., primary charged-particle beam 220 in FIG. 2) for inspection. For example, the primary charged-particle beam may be a primary electron beam. Electrons of a primary electron beam are projected onto a surface of a sample. The sample may comprise features formed on a wafer 203. The wafer 203 may alternatively be referred to herein as a substrate 203 or a wafer substrate 203. The sample may be of any materials, such as a non-conductive resist, a silicon dioxide layer, a metallic layer, or any stacked combination of any dielectric or conductive material.

The electrons of the primary electron beam may penetrate the surface of a sample for a certain depth (e.g., from several nanometers to several micrometers), interacting with particles of the sample in an interaction volume. Some electrons of the primary electron beam may elastically interact with (e.g., in a form of elastic scattering or collision) the particles in the interaction volume and may be reflected or recoiled out of the surface of the sample. An elastic interaction conserves the total kinetic energies of the bodies (e.g., electrons of the primary electron beam and the particles of sample) of the interaction, in which no kinetic energy of the interacting bodies converts to other forms of energy (e.g., heat, electromagnetic energy, etc.). Such reflected electrons generated from an elastic interaction may be referred to as backscattered electrons (BSEs). Some electrons of primary electron beam may inelastically interact with (e.g., in a form of inelastic scattering or collision) the particles in the interaction volume. An inelastic interaction does not conserve the total kinetic energies of the bodies of the interaction, in which some or all of the kinetic energy of the interacting bodies may covert to other forms of energy. For example, through the inelastic interaction, the kinetic energy of some electrons of the primary electron beam may cause electron excitation and cause generation of electrons exiting the surface of the sample, which may be referred to as secondary electrons (SEs). Some of the SEs may have sufficient energy to eventually exit the surface of sample and reach a detector, and some of the SEs may eventually exit and then re-enter the surface of sample, in particular when the surface of the sample is positively charged. Yield or emission rates of BSEs and SEs may depend on, for example, the energy of the electrons of primary electron beam and the material under inspection, among other factors. The energy of the electrons of primary electron beam may be imparted in part by its acceleration voltage (e.g., the acceleration voltage between anode 216 and cathode 218 in FIG. 2). The quantity of BSEs and SEs may be more or fewer (or even the same) than the injected electrons of primary electron beam.

By way of example, a sample may include a first layer (e.g., a resist layer on top of a wafer surface) and a second layer (e.g., a pattern layer beneath the wafer surface). Each of the first layer and the second layer may include a designed pattern (e.g., a target), such as lines, slots, corners, edges, holes, or the like. Those features may be at different heights. The primary electron beam may interact with particles in the first layer to generate SEs, and SEs generated at different locations of the target in the first layer may be used to determine geometric information of the target in the first layer. The primary electron beam may also penetrate the first layer to reach and interact with particles in the second layer to generate BSEs, and BSEs generated at different locations of the target in the second layer may be used to determine geometric information of the target in the second layer. The landing energy of the electrons of the primary electron beam determines how deep in the sample the bulk of the SEs and BSEs are generated. When the landing energy is low, a substantial proportion of both SEs and BSEs may reach the detector. When the landing energy is high, SEs increasingly fail to reach the detector and so the proportion of detected electrons that are BSEs increases.

Consistent with some embodiments of this disclosure, a computer-implemented method of measuring overlay for a sample under a scan performed by a charged-particle beam inspection apparatus may include obtaining a detector signal in response to a scan of a target of the sample. In some embodiments, the charged-particle beam inspection apparatus may include a scanning electron microscope. The sample may include a wafer.

By way of example, the charged-particle beam inspection apparatus may be an imaging system (e.g., imaging system 200 in FIG. 2). The sample may be a wafer (e.g., wafer 203 in FIG. 2) with manufactured structure (e.g., circuits) on its surface. In some embodiments, the target may be a specifically designed and manufactured structure. For example, the target may be independent of and has no functional relationship to the manufactured circuits on the wafer. In some embodiments, the target may be manufactured at a free space on the wafer not occupied by the manufactured circuits.

The detector signal may be a signal outputted by a detector (e.g., detector 206 in FIG. 2) of the charged-particle inspection apparatus in response to the scan. In some embodiments, the target may be scanned by a charged-particle beam (e.g., of a single-beam inspection apparatus) or a charged-particle beamlet (e.g., of a multi-beam inspection apparatus). During scanning of the sample, after charged particles (e.g., electrons) of a primary beam (e.g., primary beam 220 in FIG. 2) hit the surface of the sample, at least one of secondary charged particles (e.g., SEs) or backscattered charged particles (e.g., BSEs) may be emitted from the surface of the sample and directed to the detector (e.g., detector 206 in FIG. 2). In some embodiments, at least one of secondary electrons or backscattered electrons may be emitted from the target and directed to the detector to generate the detector signal.

In some embodiments, the detector signal may be a value representing a sum or a count of the detected electrons emitted from the target. In some embodiments, the detector signal may be a value representing a sum of charges of the detected electrons emitted from the target. In some embodiments, the detector signal may be visualized.

In some embodiments, the target may include a first pattern layer and a second pattern layer under the first pattern layer. Each of the first pattern layer and the second pattern layer may include a grating. The pitch of the grating in each pattern layer may be the same or different.

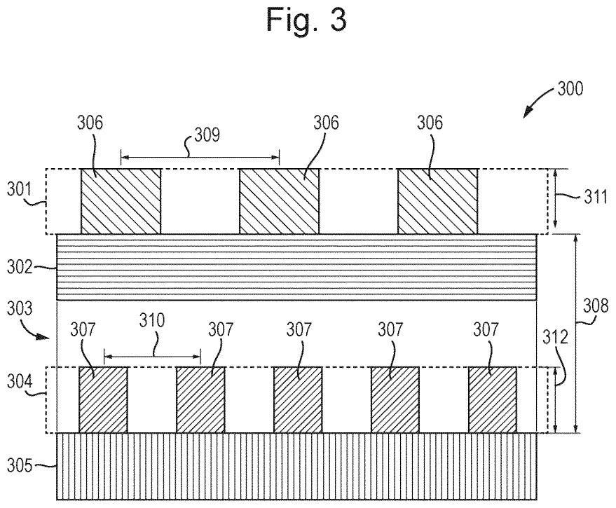

By way of example, FIG. 3 is a schematic diagram illustrating a sample that comprises an example target 300 manufactured on a substrate 305, consistent with some embodiments of the present disclosure. The substrate 305 may be the silicon wafer substrate 203. In some embodiments, target 300 may be a diffraction-based overlay target. As illustrated in FIG. 3, target 300 includes a first pattern layer 301 and a second pattern layer 304 under the first pattern layer 301. The first pattern layer 301 and second pattern layer 304 may each be of a type of a grating (e.g., a line grating).

In some embodiments, the first pattern layer 301 may be of a material of polymethyl methacrylate (PMMA). The first pattern layer 301 may be fabricated (e.g., via a coating, lithography, and etching process) on a support layer 302. The support layer 302 may also be made of PMMA. The grating of the first pattern layer 301 may comprise a plurality structures 306, that may be linear lines 306, that define peaks and troughs above the support layer 302. The height of each structure 306 above the support layer 302 may be referred to as the height 311 of the grating in the first pattern layer 301. The first pattern layer 301 may have a pitch with the pitch value 309 being the distance between centers of two adjacent structures 306 of the grating.

In some embodiments, second pattern layer 304 may be of a copper material. The second pattern layer 304 may be fabricated (e.g., via a coating, lithography, and etching process) on the substrate 305. The grating of the second pattern layer 304 may comprise a plurality structures 307, that may be linear lines 307, that define peaks and troughs above the surface of the substrate 305. The height of each structure 307 above the substrate 305 may be referred to as the height 312 of the grating in the second pattern layer 312. The second pattern layer 304 may have a pitch with the pitch value 310 being the distance between centers of two adjacent structures 307 of the grating. The pitch value 309 of the first pattern layer 301 may be different, or the same, as the pitch value 310 of the second pattern layer 304.

In some embodiments, a silicon dioxide layer 303 may separate the support layer 302 and second pattern layer 304. The gaps between the structures 307 in the second pattern layer may also be filled with silicon dioxide.

The first pattern layer 301 and the second pattern layer 304 are separated by a separation distance 308.

Consistent with some embodiments of this disclosure, a target, such as the target 300 shown in FIG. 3, may be illuminated with an electron beam, such as the primary electron beam 220. Electrons may be detected to thereby generate detection data, that may be referred to as a detector signal. Determinations of characteristics of the sample, such as overlay, may be made in a computer-implemented method based on the detection data.

According to embodiments, a model is constructed based on known physical properties of the target 300 and the expected physical response of the target 300 to illumination by electrons. The inventors have realized that the detected response of the illumination of a grating is similar to the waveform generated by the convolution of a block function and a Kernel function, such as a Gauss function. In particular, when an electron beam propagates through a structures it broadens. The convolution of a block function and a Kernel function is an effective way of modelling this physical process. Embodiments construct a model and the parameters of the model are then tuned so that the modelled detection data, i.e. the modelled detector signal, closely resembles the actual measured signal/data. The tunable parameters of the model may include the location of the block functions and the widths of the Kernel functions. The tuned values of the parameters of the model may then be used to determine characteristics of the sample, such as overlay.

The model may comprise a number of terms that combine to provide a modelled detection data. The terms of the model may include one or more of:
a) A modelled Offset;
b) A modelled contribution from the first pattern layer 301;
c) A modelled contribution from the second pattern layer 304; and
d) A modelled Interaction signal.

The modelled Offset may represent the average of the minimum signal level in the actual measured signal/data. The modelled Offset may be an electron count (in arbitrary units). An initial value of the modelled Offset may be an average minimum value of the actual measured signal/data.

The modelled contribution from the first pattern layer 301 may be referred to as a Top-Signal. The Top-Signal may be calculated as:

$$Top - Signal = {A}_{top} \times Block ( top - pitch , top - duty cycle , top - shift ) ⊗ Top - Kernel ( type , width )$$

where:
‘Aₜₒₚ’ represents the amplitude of the detected signal from the grating in the first pattern layer 301. Aₜₒₚ may be an electron count (in arbitrary units). The value of Aₜₒₚ may depend on the material properties, such as density and atomic number, as well as geometric properties, such as the height 311 of the grating in the first pattern layer 301;
‘Block( . . . )’ is a function that models the grating shape. The grating shape may be, for example, a square or rectangular wave. The value of the function may vary from 0 to 1;
‘top-pitch’ is the pitch value 309 of the first pattern layer 301. An expected value of the top-pitch may be known from the design parameters of the target 300. The expected value of the top-pitch may be initially used in the model and then varied when the model is tuned;
‘top-duty cycle’ relates to the width and spacing of the structures 306;
‘top-shift’ relates to a location reference point that, together with the later described bottom-shift, may be used to determine overlay. The top-shift may be defined in a number of different ways. For example, an expected center of a signal may represent the zero top-shift position. Positions other than the expected center of the signal would then have a top-shift value. Alternatively, the expected center of a structure 306 may represent the zero top-shift position. Positions other than the expected center of the structure 306 would then have a top-shift value. Accordingly, a top-shift value may represent the difference between the actual and expected locations of a feature, such as a structure 306;
‘⊗’ indicates a convolution operation; and
‘Top-Kernel’ is a function with the property that the integral over its width is equal to 1. The Top-Kernel is defined by the type of function, such as a Gauss function, and the width of the function.

The modelled contribution from the second pattern layer 304 may be referred to as a Bottom-Signal. The Bottom-Signal may be calculated as:

$$Bottom - Signal = {A}_{bottom} \times Block ( bottom - pitch , bottom - duty cycle , bottom - shift ) ⊗ Bottom - Kernel ( type , width )$$

where:
‘A_{bottom}’ represents the amplitude of the detected signal from the grating in the second pattern layer 304. A_{bottom} may be an electron count (in arbitrary units). The value of A_{bottom} may depend on the material properties, such as density and atomic number, as well as geometric properties, such as the height 312 of the grating in the second pattern layer 304;
‘Block( . . . )’ is a function that models the grating shape. The grating shape may be, for example, a square or rectangular wave. The value of the function may vary from 0 to 1;
‘bottom-pitch’ is the pitch value 310 of the second pattern layer 304. An expected value of the bottom-pitch may be known from the design parameters of the target 300. The expected value of the bottom-pitch may be initially used in the model and then varied when the model is tuned;
‘bottom-duty cycle’ relates to the width and spacing of the structures 307;
‘bottom-shift’ relates to a location reference point that, together with the above described top-shift, may be used to determine overlay. The bottom-shift may be defined in a number of different ways. For example, an expected center of a signal may represent the zero bottom-shift position. Positions other than the expected center of the signal would then have a bottom-shift value. Alternatively, the expected center of a structure 307 may represent the zero bottom-shift position. Positions other than the expected center of the structure 307 would then have a bottom-shift value. The bottom-shift value may represent the difference between the actual and expected locations of a feature, such as a structure 307. Overlay may be calculated as the difference between the top-shift value and the bottom-shift value;
‘⊗’ indicates a convolution operation; and
‘Bottom-Kernel’ is a function with the property that the integral over its width is equal to 1. The Bottom-Kernel is defined by the type of function, such as a Gauss function, and the width of the function. The width of the Bottom-Kernel may be a lot larger than that of the Top-Kernel. The Bottom-Kernel may therefore be similar to a sine-wave.

The Interaction signal is dependent on a point multiplication of the Top-Signal and the Bottom-Signal as well as the additional term A_{interaction}:

$$Interaction signal = {A}_{interaction} \times Top - Signal \times Bottom - Signal$$

The A_{interaction} term is dependent on the expected different physical interactions between the first pattern layer 301 and the second pattern layer 304. In particular, when an electron beam passes through the top, i.e. a peak, of the grating in the first pattern layer 301, the experienced beam broadening and signal dampening are different from when an electron beam passes through a trough of the grating. The Interaction signal includes these different physical effects in the model.

The model may be constructed by adding together all of the above-described modelled Offset, Top-Signal, Bottom-Signal, and Interaction signal.

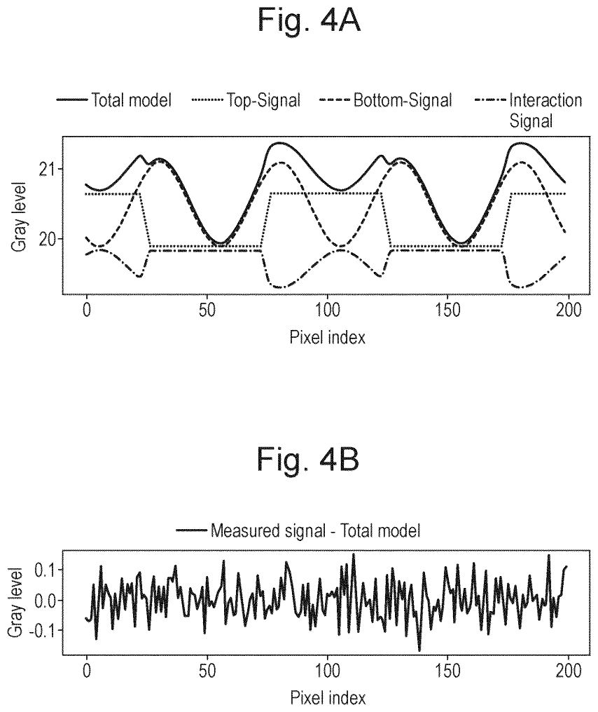

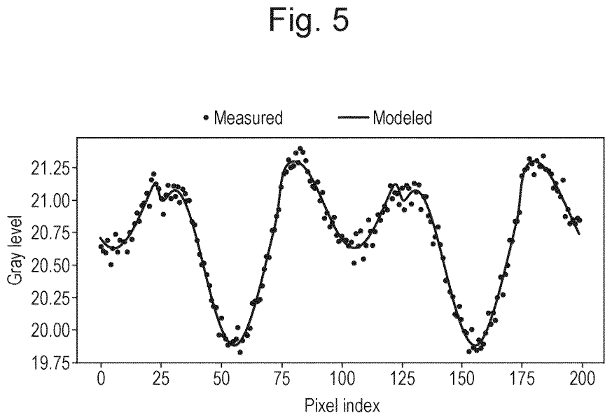

FIG. 4A shows the modelled signal and its components according to some embodiments. FIGS. 4B and 5 demonstrate the accuracy of the modelled signal. In all of FIGS. 4A, 4B and 5, the x-axis is a pixel index and relates to the location of the modelled and/or measured data/signals. In all of FIGS. 4A, 4B and 5, the y-axis is a Gray level. The Gray level may be dependent on the number of charged particles detected over a time period by a pixel of the detector and/or the intensity of a signal detected by the pixel.

FIG. 4A separately shows all of the modelled Top-Signal, Bottom-Signal and Interaction component. The ‘Total model’ line in FIG. 4A shows the summation of the contributions to the model, including the modelled Offset.

A process may be performed for tuning the parameters of the model so that the model fits well to the actual measurement of electrons following the illumination of the target.

The parameters in the terms of the model that may be tuned in order to fit the model to the measured data include the Offset, Aₜₒₚ, A_{bottom}, top-shift, bottom-shift, Top-Kernel width, Bottom-Kernel width and A_{interaction}. Increasing the number of tuned parameters may improve the accuracy of the model at the expense of increasing the complexity of fitting the model to the measured data. Decreasing the number of tuned parameters may reduce the accuracy of the model but also reduce the complexity of fitting the model to the measured data.

The tuning process may be performed by using a cost function, such as the L2-norm of the simulated and modeled signal, and, for example, a global minimizer or a combination of solving a set of linear equations and a global minimizer. Embodiments also include other techniques for fitting the model to the measured data.

FIG. 5 shows the modelled signal, i.e. ‘Total model’ line, according to embodiments when fitted to measured data. The modelled signal is the continuous line. The measured data comprises measurements at different locations, as shown by the discrete dots at different pixel indexes.

In FIG. 5, the values of the parameters that generated the modelled signal were:
Offset=19.877
Top-Kernel=(Gauss Kernel, width=5.84)
Bottom-Kernel=(Gauss Kernel, width=37.00)
Aₜₒₚ=0.751
A_{bottom}=1.469
A_{interaction}=0.648
top-shift=−0.135
bottom-shift=−18.924

FIG. 4B shows a residual signal, or error signal, that represents the difference between the measured and modelled signals. The value of the residual signal may be 0.782. The low absolute errors values in FIG. 4B show that the model is a good fit to the actual measured data.

After the model has been fitted to the measured data, the parameters of the model may be used to determine the characteristics of the target 300. In particular, the overlay may be determined in dependence on the top-shift and bottom-shift parameters of the model.

The model according to embodiments may be applied in a number of different situations. In particular, the model may be used to process received signals from a high voltage scanning electron microscope, HV-SEM, to determine the average overlay in an image of a sample 300. The averaging of the measured data suppresses noise in the measurements. However, embodiments also include not averaging the measured data so that the model determines local overlay.

Embodiments include the top-duty cycle and bottom-duty cycle of the model also being variable parameters that are tuned when the model is fitted to measured data. The model may thereby determine the average CD. The averaging of the measured data suppresses noise in the measurements. However, embodiments also include not averaging the measured data so that the model determines local CD.

Embodiments are not restricted to determining the characteristics of gratings. A line of a grating is an example of a one dimensional structure. A two dimensional structure may have, for example, an L-shape in plan view. Embodiments may be used to determine the characteristics of any features formed on a substrate including 2D structures, such as contact holes, bricks and other patterns. The Block( . . . ) function of the model may be changed so that it corresponds to the shapes of the structures being measured.

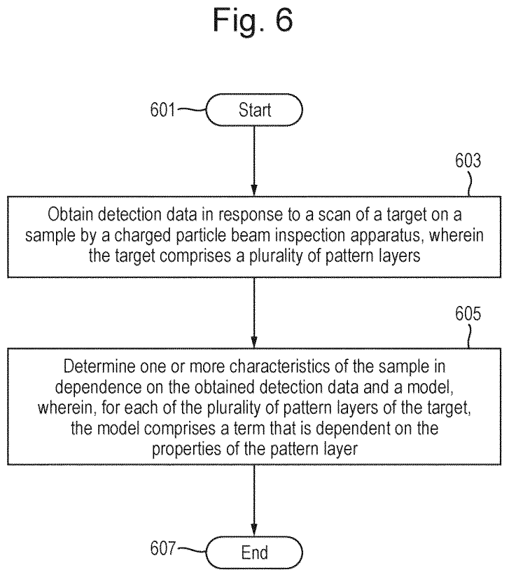

FIG. 6 shows a flowchart of a computer-implemented method of measuring characteristics of a sample under a scan performed by a charged-particle beam inspection apparatus according to an embodiment.

In step 601, the method starts.

In step 603, detection data is obtained in response to a scan of a target on a sample by a charged particle beam inspection apparatus, wherein the target comprises a plurality of pattern layers.

In step 605, one or more characteristics of the sample are determined in dependence on the obtained detection data and a model, wherein, for each of the plurality of pattern layers of the target, the model comprises a term that is dependent on the properties of the pattern layer.

In step 607, the method ends.

Embodiments also include a number of modification and variations to the above-described techniques.

Embodiments include the model using any of a number of different Kernel functions for modelling the Top-Signal and/or Bottom-Signal. A preferred Kernel function is the Gaussian Kernel because it allows accurate modelling. However, other types of Kernel function may be used, such as a Triangular Kernel, that reduce the complexity of the modelling process and thereby allow faster modelling.

Embodiments include the model using variable Kernel functions for modelling the Top-Signal and/or the Bottom-Signal. With a variable Kernel, the width of the Kernel is dependent on the location of the structures 307 below the first pattern layer 301. This may improve the accuracy of the model, at the expense of increasing the computation time, because it better represents the physical processes.

Embodiments also include the model using variable Kernel functions for modelling the Top-Signal and/or Bottom-Signal. The width of each Kernel may be dependent on the relative locations of the structures 306 in the first pattern layer 301 to the structures 307 in the second pattern layer. This may improve the accuracy of the model, at the expense of increasing the computation time, because it better represents the physical processes.

Embodiments may provide an improved determination of the characteristics of a sample 300 than optical techniques.

Embodiments may also improve on other charged particle based measurement techniques that make determinations based on arbitrary thresholds rather than a model of the actual physical processes that occur.

Embodiments may determine a characteristic based on a measurement of a single target 300. This is an advantage over techniques that require measurements from more than one target.

Embodiments have been described with reference to a target that comprises a first pattern layer 301 and a second pattern layer 304. Embodiments may also be used with other types of target, such as targets that comprise more than two pattern layers. The model according to embodiments may be modified to include terms that represent the detection of electrons from each of the more than two layers of the target and the interaction between the layers.

Embodiments have been described in the context of a sample being illuminated by an electron beam, such as primary beam 220. The electron beam may be from a single beam charged particle apparatus or a multi-beam charged particle apparatus. Embodiments more generally include the illumination of a sample by any charged particle beam.

Embodiments include a sample comprising a plurality of targets and local characteristics of the sample being determined at each target.

A non-transitory computer readable medium may be provided that stores instructions for a processor (for example, processor of controller 109 of FIG. 1) to carry out overlay measurement such as method 800 of FIG. 8 or method 900 of FIG. 9, data processing, database management, graphical display, operations of an image inspection apparatus or another imaging device, detecting a defect on a sample, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

Embodiments include the following clauses:

1. A system, comprising:
a charged-particle beam inspection apparatus configured to scan a sample that comprises a target with
a plurality of pattern layers; and
a controller including circuitry, configured to:
obtain detection data in response to a scan of the target; and
determine one or more characteristics of the sample in dependence on the obtained detection data and a model;
wherein, for each of the plurality of pattern layers of the target, the model comprises a term that is dependent on the properties of the pattern layer.

2. The system according to clause 1, wherein the controller is configured to:
determine parameters of the model such that a modelled detection signal substantially fits to the obtained detection data; and
determine one or more characteristics of the sample in dependence on the determined parameters.

3. The system according to clause 1 or 2, wherein the one or more characteristics of the sample include overlay and critical dimension.

4. The system according to any preceding clause, wherein the target comprises a first pattern layer and a second pattern layer; and
each pattern layer comprises a grating.

5. The system according to clause 4, wherein:
the grating comprised by the first pattern layer has a first pitch;
the grating comprised by the second pattern layer has a second pitch; and
the first pitch is different to the second pitch.

6. The system according to any of clauses 4 or 5, wherein the terms of the model include:
a Top-Signal that is a modelled contribution from the first pattern layer;
a Bottom-Signal that is a modelled contribution from the second pattern layer; and
an Interaction signal that models the interaction between the first pattern layer and the second pattern layer.

7. The system according to clause 6, wherein the model further comprises an Offset term for modelling an average of the minimum values of the obtained detection data.

8. The system according to any of clauses 4 to 7, wherein the Top-Signal is calculated as:

$$Top - Signal = {A}_{top} \times Block ( top - pitch , top - duty cycle , top - shift ) ⊗ Top - Kernel ( type , width )$$

where:
‘Aₜₒₚ’ represents the amplitude of the detected signal from the grating in the first pattern layer;
‘Block( . . . )’ is a function that models the grating shape;
‘top-pitch’ is the pitch value of the first pattern layer;
‘top-duty cycle’ relates to the width and spacing of the grating in the first pattern layer;
‘top-shift’ relates to a location reference point;
‘⊗’ indicates a convolution operation; and
‘Top-Kernel’ is a Kernel function.

9. The system according to any of clauses 4 to 8, wherein the Bottom-Signal is calculated as:

$$Bottom - Signal = {A}_{bottom} \times Block ( bottom - pitch , bottom - duty cycle , bottom - shift ) ⊗ Bottom - Kernel ( type , width )$$

where:
‘A_{bottom}’ represents the amplitude of the detected signal from the grating in the second pattern layer;
‘Block( . . . )’ is a function that models the grating shape;
‘bottom-pitch’ is the pitch value of the second pattern layer;
‘bottom-duty cycle’ relates to the width and spacing of the grating in the second pattern layer;
‘bottom-shift’ relates to a location reference point;
‘⊗’ indicates a convolution operation; and
‘Bottom-Kernel’ is a Kernel function.

10. The system according to clauses 8 and 9, when dependent on clauses 2 and 7, wherein the determined parameters of the model include one or more of: the Offset term, Aₜₒₚ, A_{bottom}, top-shift, bottom-shift, Top-Kernel width, Bottom-Kernel width and the Interaction signal.

11. The system according to any of clauses 8 to 10, wherein the controller is configured to determine the overlay of the sample in dependence on the determined top-shift and the determined bottom shift.

12. The system according to any preceding clause, wherein the charged-particle beam inspection apparatus comprises a scanning electron microscope, and the sample comprises a target formed on a substrate.

13. A non-transitory computer-readable medium that stores a set of instructions that is executable by at least one processor of an apparatus to cause the apparatus to perform a method, the method comprising:
obtaining detection data in response to a scan of a target by a charged particle beam inspection apparatus; determining one or more characteristics of the sample in dependence on the obtained detection data and a model;
wherein the target comprises a plurality of pattern layers and, for each of the plurality of pattern layers, the model comprises a term that is dependent on the properties of the pattern layer.

14. The non-transitory computer-readable medium according to clause 13, the method further comprising:
determining parameters of the model such that a modelled detection signal substantially fits to the obtained detection data; and
determining one or more characteristics of the sample in dependence on the determined parameters.

15. The non-transitory computer-readable medium according to clause 13 or 14, wherein the one or more characteristics of the sample include overlay and critical dimension.

16. The non-transitory computer-readable medium according to any of clauses 13 to 15, wherein the target comprises a first pattern layer and a second pattern layer; and each pattern layer comprises a grating.

17. The non-transitory computer-readable medium according to clause 16, wherein:
the grating comprised by the first pattern layer has a first pitch;
the grating comprised by the second pattern layer has a second pitch; and
the first pitch is different to the second pitch.

18. The non-transitory computer-readable medium according to any of clauses 16 or 17, wherein the terms of the model include:
a Top-Signal that is a modelled contribution from the first pattern layer;
a Bottom-Signal that is a modelled contribution from the second pattern layer; and
an Interaction signal that models the interaction between the first pattern layer and the second pattern layer.

19. The non-transitory computer-readable medium according to clause 18, wherein the model further comprises an Offset term for modelling an average of the minimum values of the obtained detection data.

20. The non-transitory computer-readable medium according to any of clauses 18 or 19, wherein the Top-Signal is calculated as:

$$Top - Signal = {A}_{top} \times Block ( top - pitch , top - duty cycle , top - shift ) ⊗ Top - Kernel ( type , width )$$

where:
‘Aₜₒₚ’ represents the amplitude of the detected signal from the grating in the first pattern layer;
‘Block( . . . )’ is a function that models the grating shape;
‘top-pitch’ is the pitch value of the first pattern layer;
‘top-duty cycle’ relates to the width and spacing of the grating in the first pattern layer;
‘top-shift’ relates to a location reference point;
‘⊗’ indicates a convolution operation; and
‘Top-Kernel’ is a Kernel function.

21. The non-transitory computer-readable medium according to any of clauses 18 to 20, wherein the Bottom-Signal is calculated as:

$$Bottom - Signal = {A}_{bottom} \times Block ( bottom - pitch , bottom - duty cycle , bottom - shift ) ⊗ Bottom - Kernel ( type , width )$$

where:
‘A_{bottom}’ represents the amplitude of the detected signal from the grating in the second pattern layer;
‘Block( . . . )’ is a function that models the grating shape;
‘bottom-pitch’ is the pitch value of the second pattern layer;
‘bottom-duty cycle’ relates to the width and spacing of the grating in the second pattern layer;
‘bottom-shift’ relates to a location reference point;
‘®’ indicates a convolution operation; and
‘Bottom-Kernel’ is a Kernel function.

22. The non-transitory computer-readable medium according to clauses 20 and 21, when dependent on clauses 14 and 19, wherein the determined parameters of the model include one or more of: the Offset term, Aₜₒₚ, A_{bottom}, top-shift, bottom-shift, Top-Kernel width, Bottom-Kernel width and the Interaction signal.

23. The non-transitory computer-readable medium according to any of clauses 20 to 22, wherein the controller is configured to determine the overlay of the sample in dependence on the determined top-shift and the determined bottom shift.

24. The non-transitory computer-readable medium according to any of clauses 13 to 23, wherein the charged-particle beam inspection apparatus comprises a scanning electron microscope, and the sample comprises a target formed on a substrate.

25. A computer-implemented method of measuring characteristics of a sample under a scan performed by a charged-particle beam inspection apparatus, the method comprising:
obtaining detection data in response to a scan of a target by a charged particle beam inspection apparatus; determining one or more characteristics of the sample in dependence on the obtained detection data and a model;
wherein the target comprises a plurality of pattern layers and, for each of the plurality of pattern layers, the model comprises a term that is dependent on the properties of the pattern layer.

26. The method according to clause 25, further comprising:
determining parameters of the model such that a modelled detection signal substantially fits to the obtained detection data; and
determining one or more characteristics of the sample in dependence on the determined parameters.

27. The method according to clause 25 or 26, wherein the one or more characteristics of the sample include overlay and critical dimension.

28. The method according to any of clauses 25 to 27, wherein the target comprises a first pattern layer and a second pattern layer; and each pattern layer comprises a grating.

29. The method according to clause 28, wherein:
the grating comprised by the first pattern layer has a first pitch;
the grating comprised by the second pattern layer has a second pitch; and
the first pitch is different to the second pitch.

30. The method according to any of clauses 28 or 29, wherein the terms of the model include:
a Top-Signal that is a modelled contribution from the first pattern layer;
a Bottom-Signal that is a modelled contribution from the second pattern layer; and
an Interaction signal that models the interaction between the first pattern layer and the second pattern layer.

31. The method according to clause 30, wherein the model further comprises an Offset term for modelling an average of the minimum values of the obtained detection data.

32. The method according to any of clauses 30 or 31, wherein the Top-Signal is calculated as:

$$Top - Signal = {A}_{top} \times Block ( top - pitch , top - duty cycle , top - shift ) ⊗ Top - Kernel ( type , width )$$

where:
‘Aₜₒₚ’ represents the amplitude of the detected signal from the grating in the first pattern layer;
‘Block( . . . )’ is a function that models the grating shape;
‘top-pitch’ is the pitch value of the first pattern layer;
‘top-duty cycle’ relates to the width and spacing of the grating in the first pattern layer;
‘top-shift’ relates to a location reference point;
‘®’ indicates a convolution operation; and
‘Top-Kernel’ is a Kernel function.

33. The method according to any of clauses 30 to 32, wherein the Bottom-Signal is calculated as:

$$Bottom - Signal = {A}_{bottom} \times Block ( bottom - pitch , bottom - duty cycle , bottom - shift ) ⊗ Bottom - Kernel ( type , width )$$

where:
‘A_{bottom}’ represents the amplitude of the detected signal from the grating in the second pattern layer;
‘Block( . . . )’ is a function that models the grating shape;
‘bottom-pitch’ is the pitch value of the second pattern layer;
‘bottom-duty cycle’ relates to the width and spacing of the grating in the second pattern layer;
‘bottom-shift’ relates to a location reference point;
‘⊗’ indicates a convolution operation; and
‘Bottom-Kernel’ is a Kernel function.

34. The method according to clauses 32 and 33, when dependent on clauses 26 and 31, wherein parameters of the model include one or more of: the Offset term, Aₜₒₚ, A_{bottom}, top-shift, bottom-shift, Top-Kernel width, Bottom-Kernel width and the Interaction signal.

35. The method according to any of clauses 32 to 34, wherein the controller is configured to determine the overlay of the sample in dependence on the determined top-shift and the determined bottom shift.

36. The method according to any of clauses 25 to 35, wherein the charged-particle beam inspection apparatus comprises a scanning electron microscope, and the sample comprises a target formed on a substrate.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A system, comprising:
a charged-particle beam inspection apparatus configured to scan a sample that comprises a target with a plurality of pattern layers; and
a controller including circuitry, configured to:
obtain detection data in response to a scan of the target; and
determine one or more characteristics of the sample in dependence on the obtained detection data and a model,
wherein, for each of the plurality of pattern layers of the target, the model comprises a term that is dependent on the properties of the pattern layer.

2. The system according to claim 1, wherein the controller is configured to:
determine parameters of the model such that a modelled detection signal substantially fits to the obtained detection data; and
determine one or more characteristics of the sample in dependence on the determined parameters.

3. The system according to claim 1, wherein the one or more characteristics of the sample include overlay and/or critical dimension.

4. The system according to claim 1, wherein the target comprises a first pattern layer and a second pattern layer; and
each pattern layer comprises a grating.

5. The system according to claim 1, wherein:
the target comprises a first pattern layer and a second pattern layer;
each pattern layer comprises a grating;
the grating comprised by the first pattern layer has a first pitch;
the grating comprised by the second pattern layer has a second pitch; and
the first pitch is different to the second pitch.

6. The system according to claim 1, wherein the terms of the model include:
a Top-Signal that is a modelled contribution from a first pattern layer;
a Bottom-Signal that is a modelled contribution from a second pattern layer; and
an Interaction signal that models an interaction between the first pattern layer and the second pattern layer.

7. The system according to claim 1, wherein the terms of the model include:
a Top-Signal that is a modelled contribution from a first pattern layer;
a Bottom-Signal that is a modelled contribution from a second pattern layer;
an Interaction signal that models an interaction between the first pattern layer and the second pattern layer; and
an Offset term for modelling an average of the minimum values of the obtained detection data.

8. The system according to claim 1, wherein the terms of the model include:
a Top-Signal that is a modelled contribution from a first pattern layer;
a Bottom-Signal that is a modelled contribution from a second pattern layer;
an Interaction signal that models an interaction between the first pattern layer and the second pattern layer; and
an Offset term for modelling an average of the minimum values of the obtained detection data; and
wherein the Top-Signal is calculated as:
$$Top - Signal = {A}_{top} \times Block ( top - pitch , top - duty cycle , top - shift ) ⊗ Top - Kernel ( type , width )$$
where:
‘Aₜₒₚ’ represents the amplitude of the detected signal from a grating in the first pattern layer;
‘Block( . . . )’ is a function that models the grating shape;
‘top-pitch’ is a pitch value of the first pattern layer;
‘top-duty cycle’ relates to the width and spacing of the grating in the first pattern layer;
‘top-shift’ relates to a location reference point;
‘237’ indicates a convolution operation; and
‘Top-Kernel’ is a Kernel function.

9. The system according to claim 1, wherein the terms of the model include:
a Top-Signal that is a modelled contribution from a first pattern layer;
a Bottom-Signal that is a modelled contribution from a second pattern layer;
an Interaction signal that models an interaction between the first pattern layer and the second pattern layer; and
an Offset term for modelling an average of the minimum values of the obtained detection data; and
wherein the Bottom-Signal is calculated as:
$$Bottom - Signal = {A}_{bottom} \times Block ( bottom - pitch , bottom - duty cycle , bottom - shift ) ⊗ Bottom - Kernel ( type , width )$$
where:
‘A_{bottom}’ represents the amplitude of the detected signal from a grating in the second pattern layer;
‘Block( . . . )’ is a function that models the grating shape;
‘bottom-pitch’ is a pitch value of the second pattern layer;
‘bottom-duty cycle’ relates to the width and spacing of the grating in the second pattern layer;
‘bottom-shift’ relates to a location reference point;
‘⊗’ indicates a convolution operation; and
‘Bottom-Kernel’ is a Kernel function.

10. The system according claim 1, wherein the terms of the model include:
a Top-Signal that is a modelled contribution from a first pattern layer;
a Bottom-Signal that is a modelled contribution from a second pattern layer;
an Interaction signal that models an interaction between the first pattern layer and the second pattern layer; and
an Offset term for modelling an average of the minimum values of the obtained detection data; and
wherein the Top-Signal is calculated as:
$$Top - Signal = {A}_{top} \times Block ( top - pitch , top - duty cycle , top - shift ) ⊗ Top - Kernel ( type , width )$$
where:
‘Aₜₒₚ’ represents the amplitude of the detected signal from a grating in the first pattern layer;
‘Block( . . . )’ is a function that models the grating shape;
‘top-pitch’ is the pitch value of the first pattern layer;
‘top-duty cycle’ relates to the width and spacing of the grating in the first pattern layer;
‘top-shift’ relates to a location reference point;
‘237’ indicates a convolution operation; and
‘Top-Kernel’ is a Kernel function;
wherein the Bottom-Signal is calculated as:
$$Bottom - Signal = {A}_{bottom} \times Block ( bottom - pitch , bottom - duty cycle , bottom - shift ) ⊗ Bottom - Kernel ( type , width )$$
where:
‘A_{bottom}’ represents the amplitude of the detected signal from a grating in the second pattern layer;
‘Block( . . . )’ is a function that models the grating shape;
‘bottom-pitch’ is the pitch value of the second pattern layer;
‘bottom-duty cycle’ relates to the width and spacing of the grating in the second pattern layer;
‘bottom-shift’ relates to a location reference point;
‘237’ indicates a convolution operation; and
‘Bottom-Kernel’ is a Kernel function; and
wherein determined parameters of the model include one or more selected from: the Offset term, Aₜₒₚ, A_{bottom}, top-shift, bottom-shift, Top-Kernel width, Bottom-Kernel width and the Interaction signal.

11. The system according to claim 1, wherein the terms of the model include:
a Top-Signal that is a modelled contribution from a first pattern layer;
a Bottom-Signal that is a modelled contribution from a second pattern layer;
an Interaction signal that models an interaction between the first pattern layer and the second pattern layer; and
an Offset term for modelling an average of the minimum values of the obtained detection data; and
wherein the Top-Signal is calculated as:
$$Top - Signal = {A}_{top} \times Block ( top - pitch , top - duty cycle , top - shift ) ⊗ Top - Kernel ( type , width )$$
where:
‘Aₜₒₚ’ represents the amplitude of the detected signal from a grating in the first pattern layer;
‘Block( . . . )’ is a function that models the grating shape;
‘top-pitch’ is the pitch value of the first pattern layer;
‘top-duty cycle’ relates to the width and spacing of the grating in the first pattern layer;
‘top-shift’ relates to a location reference point;
‘237’ indicates a convolution operation; and
‘Top-Kernel’ is a Kernel function;
wherein the Bottom-Signal is calculated as:
$$Bottom - Signal = {A}_{bottom} \times Block ( bottom - pitch , bottom - duty cycle , bottom - shift ) ⊗ Bottom - Kernel ( type , width )$$
where:
‘A_{bottom}’ represents the amplitude of the detected signal from a grating in the second pattern layer;
‘Block( . . . )’ is a function that models the grating shape;
‘bottom-pitch’ is the pitch value of the second pattern layer;
‘bottom-duty cycle’ relates to the width and spacing of the grating in the second pattern layer;
‘bottom-shift’ relates to a location reference point;
‘237’ indicates a convolution operation; and
‘Bottom-Kernel’ is a Kernel function; and
wherein the controller is configured to determine the overlay of the sample in dependence on the determined top-shift and the determined bottom-shift.

12. The system according claim 1, wherein the charged-particle beam inspection apparatus comprises a scanning electron microscope, and the sample comprises a target formed on a substrate.

13. A non-transitory computer-readable medium that stores a set of instructions that is executable by at least one processor of an apparatus to cause the apparatus to at least:
obtain detection data in response to a scan of a target by a charged particle beam inspection apparatus;
determine one or more characteristics of the sample in dependence on the obtained detection data and a model,
wherein the target comprises a plurality of pattern layers and, for each of the plurality of pattern layers, the model comprises a term that is dependent on properties of the pattern layer.

14. The non-transitory computer-readable medium according to claim 13, wherein the instructions are further configured to, when executed, cause the apparatus to:
determine parameters of the model such that a modelled detection signal substantially fits to the obtained detection data; and
determine one or more characteristics of the sample in dependence on the determined parameters.

15. The non-transitory computer-readable medium according to claim 13, wherein the one or more characteristics of the sample include overlay and/or critical dimension.

16. A method comprising:
obtaining detection data in response to a scan of a target of a sample by a charged-particle beam inspection apparatus;
determining, by a hardware computer system, one or more characteristics of the sample in dependence on the obtained detection data and a model,
wherein the target comprises a plurality of pattern layers and, for each of the plurality of pattern layers, the model comprises a term that is dependent on properties of the pattern layer.

17. The method according to claim 16, further comprising:
determining parameters of the model such that a modelled detection signal substantially fits to the obtained detection data; and
determining one or more characteristics of the sample in dependence on the determined parameters.

18. The method according to claim 16, wherein the one or more characteristics of the sample include overlay and critical dimension.

19. The method according to claim 16, wherein the target comprises a first pattern layer and a second pattern layer; and
each pattern layer comprises a grating.

20. The method according to claim 19, wherein:
the grating comprised by the first pattern layer has a first pitch;
the grating comprised by the second pattern layer has a second pitch; and
the first pitch is different to the second pitch.
